(19) United States
(12) Patent Application Publication
(10) Pub. No.: US 2012/0074432 A1
(43) Pub. Date: Mar. 29, 2012

(54) LED PACKAGE MODULE AND MANUFACTURING METHOD THEREOF

(75) Inventor: Wei Jen Chou, Taipei County (TW)

(73) Assignee: AmTRAN TECHNOLOGY CO., LTD, Taipei County (TW)

(21) Appl. No.: 12/893,708

(22) Filed: Sep. 29, 2010

(51) Int. Cl. H01L 33/48; H01L 33/52

(52) U.S. Cl. 257/88; 438/27; 257/E33.059; 257/E33.056

(57) ABSTRACT

A light emitting diode (LED) package module and the manufacturing method thereof are presented. A plurality of LEDs and a plurality of semiconductor elements are disposed on a silicon substrate, and then a plurality of lenses is formed above the positions of the plurality of the LEDs, and the plurality of the lenses is corresponding to the plurality of the LEDs. Then, a plurality of package units is defined on the silicon substrate, and each package unit has a semiconductor element and at least one LED. After that, the silicon substrate is cut to form a plurality of LED package modules, and each LED package module has at least one package unit.

### BACKGROUND OF THE INVENTION

1. Field of the Invention

The present invention relates to a diode package module and the manufacturing method thereof, and more particularly to a light emitting diode (LED) package module and a manufacturing method thereof.

2. Related Art

Presently, LED package modules applied in back light units (BLUs) mostly adopt a plastic leaded chip carrier (PLCC) 2, 4, 6 packaging mode to package an LED on a substrate. A cavity is located on the substrate, and the LED is packaged in the cavity, and thus the process is convenient. However, as the LED is packaged in the cavity in this packaging manner, the cavity must have a size large enough to accommodate the LED, and as a result, the LED package module after packaging usually has problems of excessively large size, poor heat dissipation, and being difficult to be used in fabricating an optical lens to increase light extraction efficiency and change light profile.

Moreover, when the packaged LED simultaneously comprises a Red LED, a Blue LED and a Green LED, as the three LEDs are packaged in the same cavity and the three LEDs emit light respectively, it is impossible to make each light profile of the three colors self-symmetric, and thus increasing the difficulty of mixing light when the LED package modules is applied in BLUs. Meanwhile, in order to pursuit better luminance and color management, sensors such as light sensors or color sensors are usually used for feedback control; however, due to limitations of the volume of the sensors and the LED package module, as well as the size of the cavity, it is difficult to dispose enough sensors in the LED package module, which may cause insufficiency of the feedback area of the BLU. Then, this in turns results in unavailability of real-time control on luminous intensity, color temperature and color of the LED.

In recent years, substrates made of ceramic materials have been gradually used in manufacturing the LED package to solve the problem of poor heat dissipation and limited package size due to the cavity size existing in the PLCC 2, 4, 6 packaging mode. However, the packaging mode using a ceramic substrate cannot directly dispose other semiconductor elements, such as sensors and Zener diodes, on the substrate during the process of disposing LEDs on the substrate; instead, other processing procedures needs to be performed on the ceramic substrate before and after LEDs are disposed on the ceramic substrate, so as to successfully dispose the semiconductor elements, such as sensors and Zener diodes, on the ceramic substrate.

Moreover, in this packaging mode for manufacturing LED package modules, only LED package modules of one singular specification and size can usually be manufactured in one singular process, and can only be applied in the BLUs of one singular form, for example, only being applied in a direct-type BLU or an edge-type BLU. Therefore, in manufacture of conventional LED package modules, in order to be used in cooperation with BLUs of different forms, multiple manufacturing processes must be performed to obtain LED package modules of different sizes, thus problems of complicated manufacturing process and high manufacturing cost occur.

### SUMMARY OF THE INVENTION

Accordingly, the present invention provides an LED package module, to solve problems including complication of conventional manufacturing processes of LED package modules, high manufacturing cost, and an excessively large size, poor heat dissipation of manufactured LED package module, as well as the problem of unavailability of real-time control on luminous intensity, color temperature, and color of the LED.

The present invention provides a manufacturing method of an LED package module, which comprises: providing a silicon substrate; electrically disposing a plurality of LEDs on the silicon substrate; electrically disposing a plurality of semiconductor elements on the silicon substrate; disposing a layer of encapsulant layer or a plurality of encapsulants on the silicon substrate to cover the plurality of LEDs and the plurality of semiconductor elements for forming a plurality of package units, wherein each package unit includes a semiconductor element and an LED; forming a plurality of lenses on the encapsulant or the plurality of encapsulants above the positions of the plurality of LEDs, in which the plurality of lenses is corresponding to the plurality of LEDs vertically; and cutting the silicon substrate, to form a plurality of LED package modules, in which each LED package module has at least one package unit.

The present invention further provides an LED package module, which comprises a silicon substrate and at least one package unit. The package unit is disposed on the silicon substrate, and the package unit has at least one LED, a semiconductor element, and a plurality of encapsulants. The plurality of encapsulants encapsulates the at least one LED and the semiconductor element respectively, and at least one of encapsulants has a lens, disposed above the at least one LED and corresponding to the at least one LED vertically.

The present invention still further provides an LED package module, which comprises a silicon substrate and at least one package unit. The at least one package unit is electrically disposed on the silicon substrate, and the at least one package unit has at least one LED, a semiconductor element, and a layer of encapsulant. The layer of encapsulant encapsulates the at least one LED and the semiconductor element, and the layer of encapsulant has at least one lens, disposed above the at least one LED and corresponding to the at least one LED vertically.

The efficacy of the present invention lies in that, LEDs and semiconductor elements (such as sensors and Zener diodes) can be electrically disposed on a silicon substrate in the same process, such that the LEDs are modulated by the semiconductor elements and have the performance of protection against static electricity and real-time control on luminous intensity, color temperature, and color. Moreover, in the subsequent processes, the silicon substrate can be directly cut into particular shapes according to use requirements of the user, to obtain the LED package modules of different sizes, so as to reduce the manufacturing and producing cost of the LED package modules and to assemble the LED package modules on BLUs of different forms according to requirements. Moreover, due to the characteristics of the silicon substrate, such as low-thermal expansion coefficient and high-thermal conductivity, the LED package module has good heat dissipation efficiency.

The description regarding above summary of the present invention and the description regarding the following embodiments are used for illustrating and explaining principles of the present invention and providing further explanations of claim scopes in this invention.

### BRIEF DESCRIPTION OF THE DRAWINGS

The present invention will become more fully understood from the detailed description given herein below for illustration only, and thus are not limitative of the present invention, and wherein:

FIG. 1 is a flow chart of a manufacturing process of a first embodiment of the present invention;

FIG. 2 is a schematic top view of the first embodiment of the present invention;

FIG. 3 is a schematic side view of the first embodiment of the present invention;

FIG. 4 is a schematic top view of LED package modules having different sizes in the first embodiment of the present invention;

FIG. 5 is a schematic side view of a second embodiment of the present invention; and

FIG. 6 is a schematic side view of another embodiment of the present invention.

### DETAILED DESCRIPTION OF THE INVENTION

An LED package module of the present invention is applied in a BLU such as a direct-type BLU or an edge-type BLU, to act as a light source of the BLU.

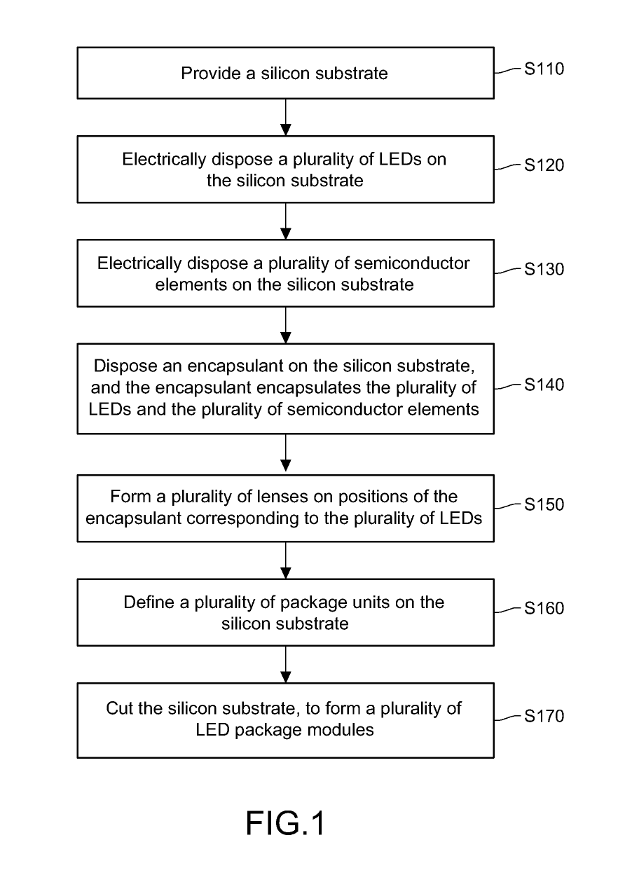

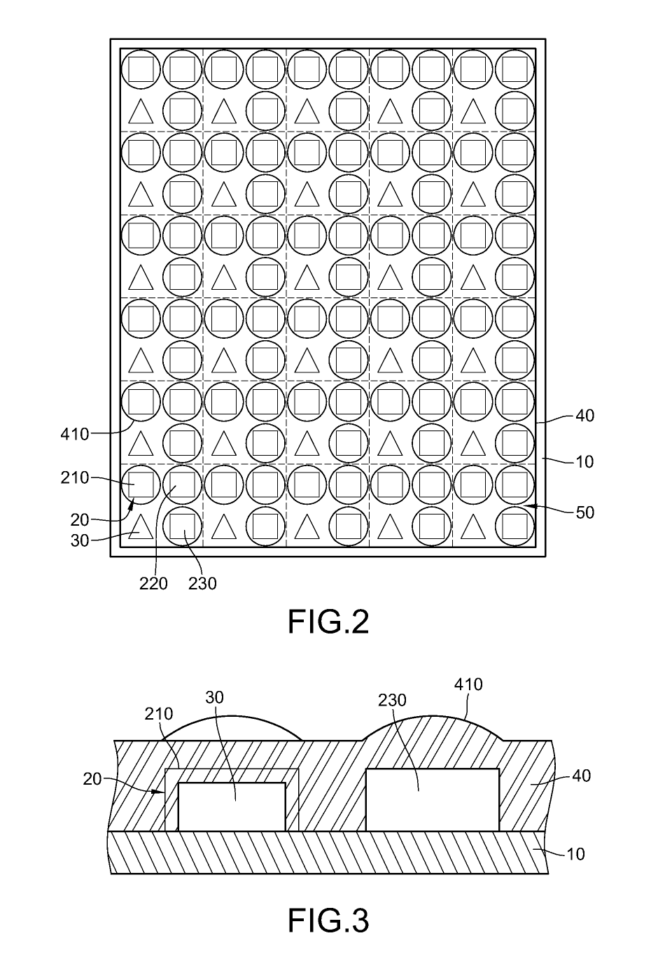

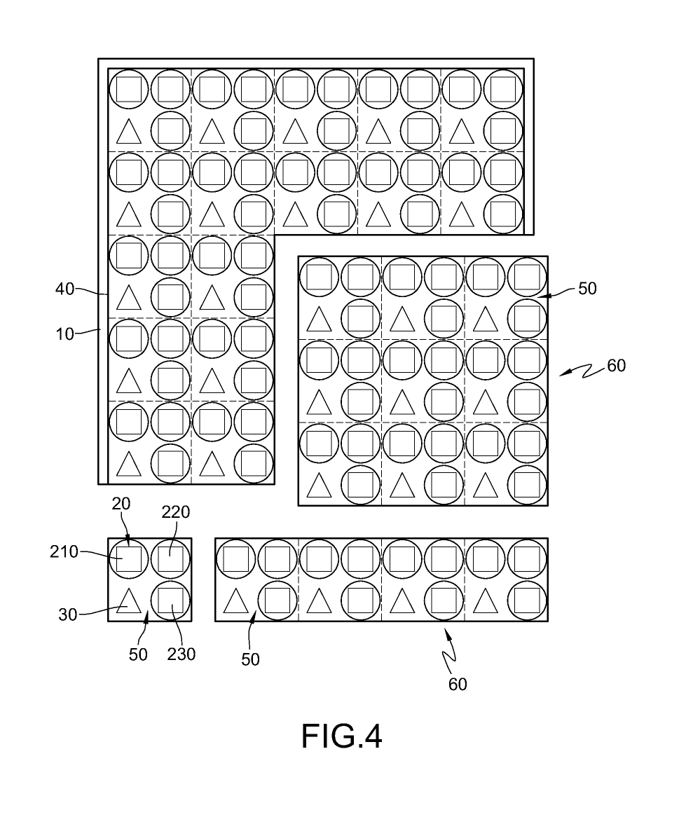

Referring to FIGS. 1 to 4, a manufacturing method of a light emitting diode (LED) package module according to a first embodiment of the present invention includes the following steps. A silicon substrate 10 is first provided (S110), then a plurality of LEDs 20 are electrically disposed on the silicon substrate 10 (S120), and a plurality of semiconductor elements 30 are electrically disposed on the silicon substrate 10 (S130). The plurality of LEDs 20 and the plurality of semiconductor elements 30 are arranged on the silicon substrate 10 in the form of an array, and the plurality of semiconductor elements 30 are disposed among the plurality of LEDs 20. The plurality of LEDs 20 are respectively LEDs emitting red light, blue light, and green light, and the plurality of semiconductor elements 30 may be, but are not limited to, Zener diodes and sensors, such as thermal sensors, light sensors, color sensors and so forth.

After that, a layer of encapsulant 40 is disposed on the silicon substrate 10 (S140). The layer of encapsulant 40 is made of a light-transmissive material. The layer of encapsulant 40 encapsulates the plurality of LEDs 20 and the plurality of semiconductor elements 30. Then, a plurality of lenses 410 is formed on the layer of encapsulant 40 at positions corresponding to the plurality of LEDs 20 (S150), in which the plurality of lenses 40 is vertically corresponding to the plurality of LEDs 20. Moreover, the plurality of lenses 40 may have the same optical structure or different optical structures, for example, have the same curvature or different curvatures. In this embodiment, the plurality of lenses 40 having the same optical structure is taken as an example, but the present invention is not limited thereto.

Then, a plurality of package units 50 is defined on the silicon substrate 10 (S160). Each package unit 50 comprises one semiconductor element 30 and three LEDs 20, and the three LEDs respectively are an LED 210 for emitting red light, an LED 220 for emitting blue light, and an LED 230 for emitting green light.

Finally, the silicon substrate 10 is cut according to different use requirements, to obtain a plurality of LED package modules 60 (S170). For example, a user may cut the silicon substrate 10 into particular shapes, such as squares or strips, according to different light intensity requirements or the design of the BLUs, to obtain LED package modules 60 of different sizes, and each LED package module 60 has at least one package module 50.

Therefore, when the LED package module 60 is applied in a BLU (not shown), through the plurality of lenses 410 having the same optical structure and formed by the layer of encapsulant 40, a symmetric light profile is provided, after the plurality of LEDs 20 emits light of different colors. Meanwhile, when the semiconductor element 30 in the package unit 50 is a Zener diode, protection against static discharge is provided for the plurality of LEDs 20; and when the semiconductor element 30 is a sensor, color, temperature, and luminance control on the light signals fed back by each LED 20 is performed directly. Therefore, the problem of insufficient feed back area existing in the conventional LED package modules is solved.

In addition, in the first embodiment of the present invention, the plurality of LEDs is exemplified by LEDs of different light colors; however, in other embodiments of the present invention, a plurality of LEDs of the same light color may be adopted.

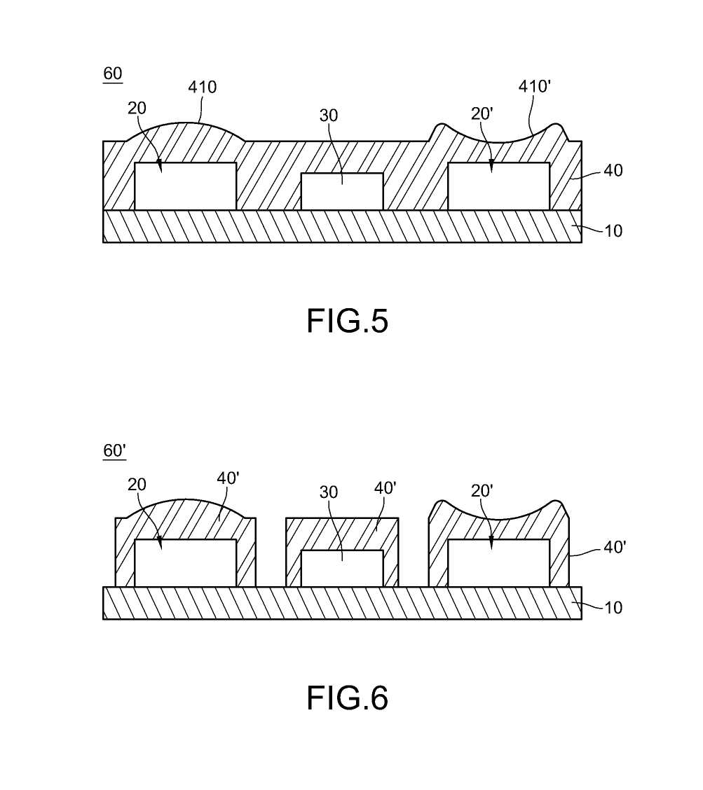

As shown in FIG. 5, an LED package module 60 according to a second embodiment of the present invention comprises a silicon substrate 10, a plurality of LEDs 20, 20′, a semiconductor element 30 and a layer of encapsulant 40. The plurality of LEDs 20, 20′ and the semiconductor element 30 are electrically disposed on the silicon substrate 10. The plurality of LEDs 20, 20′ is LEDs emitting white light and having different color temperatures. The semiconductor element 30 is a light sensor, a thermal sensor, or a color sensor. The semiconductor element 30 is electrically disposed among the plurality of LEDs 20 and 20′, to acquire feed back signals and modulate light intensity, light color, or color temperature of the LEDs 20, 20′.

It should be noted that, in the previous embodiment, a single layer of encapsulant 40 is used to encapsulate the LEDs 20, 20′ and the semiconductor element 30. In an LED package module 60′ according to another embodiment of the present invention, a plurality of independent encapsulants 40′ may also be used to encapsulate the LEDs 20, 20′ and the semiconductor element 30, as shown in FIG. 6.

The efficacy of the present invention lies in that, the characteristics of low-thermal expansion coefficient and high-thermal conductivity of the silicon substrate can effectively promote the heat dissipation of the LED, so as to avoid damages on the silicon substrate caused by the heat spot formed on the silicon substrate by the LED. Meanwhile, in the manufacture of the LED package module, by using the silicon substrate, the sensor, the Zener diode, or other types of semiconductor elements may be electrically disposed on the silicon substrate together with the LED before encapsulant encapsulates the LED, that is, no other processes are needed to dispose these semiconductor elements on the LED package module. Therefore, the assembling time and the manufacturing cost of the LED package module are reduced. Moreover, in subsequent applications, the silicon substrate may be directly cut into particular shapes to obtain the LED package modules of different sizes according to use requirements of the user, so as to be directly assembled on BLUs, and thus the manufacturing and producing cost of the LED package modules of different sizes are reduced.

What is claimed is:

1. A manufacturing method of a light emitting diode (LED) package module, comprising:
providing a silicon substrate;
electrically disposing a plurality of LEDs on the silicon substrate;
electrically disposing a plurality of semiconductor elements on the silicon substrate;
forming a plurality of lenses above positions of the plurality of LEDs, wherein the plurality of lenses are respectively corresponding to the plurality of LEDs;
defining a plurality of package units on the silicon substrate, wherein each package unit has a semiconductor element and at least one LED; and
cutting the silicon substrate, to form a plurality of LED package modules, wherein each LED package module has at least one package unit.

2. The manufacturing method of the LED package module according to claim 1, wherein the plurality of LEDs and the plurality of semiconductor elements are arranged on the silicon substrate in the form of an array, and the plurality of semiconductor elements are distributed among the plurality of LEDs.

3. The manufacturing method of the LED package module according to claim 1, further comprising: disposing a plurality of encapsulants on the silicon substrate before forming the plurality of lenses, and encapsulating the plurality of LEDs and the plurality of semiconductor elements, wherein the plurality of encapsulants are located among the plurality of LEDs and the plurality of lenses.

4. The manufacturing method of the LED package module according to claim 1, further comprising: disposing a layer of encapsulant on the silicon substrate before forming the plurality of lenses, and encapsulating the plurality of LEDs and the plurality of semiconductor elements, wherein the layer of encapsulant is located among the plurality of LEDs and the plurality of lenses.

5. The manufacturing method of the LED package module according to claim 4, wherein the step of forming the plurality of lenses is to form lenses having the same optical structure on the layer of encapsulant at positions corresponding to the plurality of LEDs.

6. The manufacturing method of the LED package module according to claim 4, wherein the step of forming the plurality of lenses is to form lenses having different optical structures on the layer of encapsulant at positions corresponding to the plurality of LEDs.

7. The manufacturing method of the LED package module according to claim 1, wherein the step of electrically disposing the plurality of semiconductor elements on the silicon substrate is to electrically dispose a plurality of Zener diodes and/or a plurality of sensors on the silicon substrate.

8. The manufacturing method of the LED package module according to claim 7, wherein the step of electrically disposing the plurality of semiconductor elements on the silicon substrate is to electrically dispose a plurality of thermal sensors, a plurality of light sensors, or a plurality of color sensors on the silicon substrate.

9. A light emitting diode (LED) package module, comprising:
a silicon substrate; and
at least one package unit, electrically disposed on the silicon substrate, and having at least one LED, a semiconductor element, and a layer of encapsulant, wherein the layer of encapsulant encapsulates the LED and the semiconductor element, the layer of encapsulant has at least one lens, disposed above the LED and corresponding to the LED vertically.

10. The LED package module according to claim 9, wherein the package unit comprises a plurality of the LEDs, and the layer of encapsulant has a plurality of the lenses, disposed above the plurality of LEDs and corresponding to the plurality of the LEDs.

11. The LED package module according to claim 10, wherein the plurality of the lenses have the same optical structure.

12. The LED package module according to claim 10, wherein the plurality of the lenses have different optical structures.

13. The LED package module according to claim 9, wherein the semiconductor element is a Zener diode or a sensor.

14. The LED package module according to claim 13, wherein the sensor is a thermal sensor, a light sensor, or a color sensor.

15. A light emitting diode (LED) package module, comprising:
a silicon substrate; and
at least one package unit, electrically disposed on the silicon substrate, and having at least one LED, a semiconductor element, and a plurality of encapsulants, wherein the plurality of encapsulants respectively encapsulates the at least one LED and the semiconductor element, and at least one of encapsulants has a lens, disposed above the at least one LED and corresponding to the at least one LED vertically.

16. The LED package module according to claim 15, wherein the package unit comprises a plurality of the LEDs, the plurality of encapsulants have a plurality of lenses, disposed above the plurality of LEDs and corresponding to the plurality of the LEDs.

17. The LED package module according to claim 16, wherein the plurality of the lenses have the same optical structure.

18. The LED package module according to claim 16, wherein the plurality of the lenses have different optical structures.

19. The LED package module according to claim 15, wherein the semiconductor element is a Zener diode or a sensor.

20. The LED package module according to claim 19, wherein the sensor is a thermal sensor, a light sensor, or a color sensor.
